(19) United States
(12) Patent Application Publication
(10) Pub. No.: US 2026/0271279 A1
(43) Pub. Date: Sep. 10, 2026

(54) SEMICONDUCTOR DEVICES HAVING PERIPHERAL CIRCUIT REGIONS

(71) Applicant: SAMSUNG ELECTRONICS CO., LTD., Suwon-si (KR)

(72) Inventors: Taejin BAE, Suwon-si (KR); Jinwoo HAN, Suwon-si (KR)

(73) Assignee: SAMSUNG ELECTRONICS CO., LTD., Suwon-si (KR)

(21) Appl. No.: 19/555,298

(22) Filed: Mar. 3, 2026

(30) Foreign Application Priority Data
Mar. 5, 2025 (KR) 10-2025-0028012

(51) Int. Cl. H10B 12/00

(52) U.S. Cl. CPC H10B 12/50; H10B 12/09; H10B 12/30

(57) ABSTRACT

A semiconductor device according to an embodiment includes a first structure including a first substrate, wherein the first substrate includes a memory cell region and a first peripheral circuit region; a second structure overlapping the first structure in a vertical direction and including a second substrate, wherein the second substrate includes a core circuit region and a second peripheral circuit region; and peripheral through-vias penetrating the second substrate in the vertical direction and electrically connected to the first structure. The first peripheral circuit region includes peripheral active patterns, a peripheral bit line extending in the vertical direction and contacting the peripheral active patterns; peripheral gate electrodes overlapping the peripheral active patterns in the vertical direction; and a peripheral interconnection structure electrically connected to at least one of the peripheral bit line or the peripheral gate electrodes. The peripheral through-vias are electrically connected to the peripheral interconnection structure.

### CROSS-REFERENCE TO RELATED APPLICATIONS

This application claims benefit of priority to Korean Patent Application No. 10-2025-0028012 filed on Mar. 5, 2025 in the Korean Intellectual Property Office, the disclosure of which is incorporated herein by reference in its entirety.

### BACKGROUND

The present inventive concept relates to a semiconductor device including a peripheral circuit region.

As the demand for high performance, high speed, and/or multifunctionality of semiconductor devices increases, a degree of integration of semiconductor devices is increasing. In manufacturing a semiconductor device with a fine pattern corresponding to the trend for a high degree of integration of semiconductor devices, it is required to implement patterns having a fine width or a fine separation distance. In addition, it is required to reduce a size of the semiconductor device.

### SUMMARY

An aspect of the present inventive concept is to provide a semiconductor device including a peripheral interconnection structure.

A semiconductor device according to example embodiments may include a first structure including a first substrate, wherein the first substrate includes a memory cell region and a first peripheral circuit region; a second structure overlapping the first structure in a vertical direction and including a second substrate, wherein the second substrate includes a core circuit region and a second peripheral circuit region; and peripheral through-vias penetrating the second substrate in the vertical direction and electrically connected to the first structure. The memory cell region may include cell active patterns extending in a first horizontal direction and disposed to be spaced apart from each other in the vertical direction; a cell bit line extending in the vertical direction and contacting the cell active patterns; cell gate electrodes overlapping the cell active patterns in the vertical direction and extending in a second horizontal direction, intersecting the first horizontal direction; and a cell interconnection structure disposed on the cell active patterns, the cell bit line, and the cell gate electrodes, and electrically connected to at least one of the cell bit line or the cell gate electrodes. The first peripheral circuit region may include peripheral active patterns extending in the first horizontal direction; a peripheral bit line extending in the vertical direction and contacting the peripheral active patterns; peripheral gate electrodes overlapping the peripheral active patterns in the vertical direction and extending in the second horizontal direction; and a peripheral interconnection structure disposed on the peripheral active patterns, the peripheral bit line and the peripheral gate electrodes, and electrically connected to at least one of the peripheral bit line or the peripheral gate electrodes. The peripheral through-vias may be electrically connected to the peripheral interconnection structure.

A semiconductor device according to example embodiments may include a first structure including a first substrate, wherein the first substrate includes a memory cell region and a first peripheral circuit region; a second structure overlapping the first structure in a vertical direction and including a second substrate, wherein the second substrate includes a core circuit region and a second peripheral circuit region; and peripheral through-vias penetrating the second substrate in the vertical direction and electrically connected to the first structure. The memory cell region may include cell active patterns extending in a first horizontal direction and disposed to be spaced apart from each other in the vertical direction; a cell bit line extending in the vertical direction and contacting the cell active patterns; cell gate electrodes overlapping the cell active patterns in the vertical direction and extending in a second horizontal direction, intersecting the first horizontal direction; and a cell interconnection structure disposed on the cell active patterns, the cell bit line, and the cell gate electrodes, and electrically connected to at least one of the cell bit line or the cell gate electrodes. The first peripheral circuit region may include a peripheral interconnection structure disposed at the same level as the cell interconnection structure. The cell interconnection structure may include cell interconnection layers disposed to be spaced apart from each other in the vertical direction, and cell vias connecting the cell interconnection layers. The peripheral interconnection structure may include peripheral interconnection layers and a peripheral via, disposed at the same level as the cell interconnection layers and the cell via, respectively. A horizontal width of one of the peripheral interconnection layers may be greater than a horizontal width of one of the cell interconnection layers. The peripheral through-vias may be electrically connected to the peripheral interconnection structure.

A semiconductor device according to example embodiments may include a first structure including a first substrate, wherein the first substrate includes a memory cell region and a first peripheral circuit region; a second structure overlapping the first structure in a vertical direction and including a second substrate, wherein the second substrate includes a core circuit region and a second peripheral circuit region; and peripheral through-vias penetrating the second substrate in the vertical direction and electrically connected to the first structure. The memory cell region may include cell active patterns extending in a first horizontal direction and disposed to be spaced apart from each other in the vertical direction; a cell bit line extending in the vertical direction and contacting the cell active patterns; cell gate electrodes overlapping the cell active patterns in the vertical direction and extending in a second horizontal direction, intersecting the first horizontal direction; and a cell interconnection structure disposed on the cell active patterns, the cell bit line, and the cell gate electrodes, and electrically connected to at least one of the cell bit line or the cell gate electrodes. The first peripheral circuit region may include peripheral active patterns extending in the first horizontal direction; a peripheral bit line extending in the vertical direction and contacting the peripheral active patterns; peripheral gate electrodes overlapping the peripheral active patterns in the vertical direction and extending in the second horizontal direction; and a peripheral interconnection structure disposed on the peripheral active patterns, the peripheral bit line and the peripheral gate electrodes, and electrically connected to at least one of the peripheral bit line or the peripheral gate electrodes. The second peripheral circuit region may include a peripheral transistor on the second substrate; a lower interconnection structure disposed on the peripheral transistor and connected to the peripheral transistor and the peripheral through-via; an upper interconnection structure on the lower interconnection structure; and an input/output pad on the upper interconnection structure. The peripheral through-vias may be electrically connected to the peripheral interconnection structure.

### BRIEF DESCRIPTION OF DRAWINGS

The and other aspects, features, and advantages of the present inventive concept will be more clearly understood from the following detailed description, taken in conjunction with the accompanying drawings.

FIG. 1 is a schematic perspective view of a semiconductor device according to an example embodiment.

FIG. 2 is a circuit diagram of a memory cell in a memory cell region according to an example embodiment.

FIG. 3 is a plan view of a first structure.

FIG. 4 is a plan view of a first memory cell region of a first structure.

FIG. 5 is a vertical cross-sectional view taken along line I-I’ of the semiconductor device illustrated in FIG. 3.

FIG. 6 is an enlarged view of a portion of the semiconductor device illustrated in FIG. 5.

FIG. 7 is a vertical cross-sectional view taken along line III-III’ of the memory cell region illustrated in FIG. 4.

FIG. 8 is a vertical cross-sectional view of a peripheral circuit region of a semiconductor device according to an example embodiment.

FIG. 9 is a flow chart of a method for manufacturing a semiconductor device according to an example embodiment.

FIGS. 10A-16B are plan views and vertical cross-sectional views illustrating a method for manufacturing a semiconductor device according to an example embodiment according to a process sequence.

FIGS. 17 and 18 are vertical cross-sectional views of semiconductor devices according to example embodiments.

FIGS. 19 and 20 are vertical cross-sectional views of semiconductor devices according to example embodiments.

### DETAILED DESCRIPTION

Hereinafter, preferred embodiments will be described with reference to the attached drawings as follows.

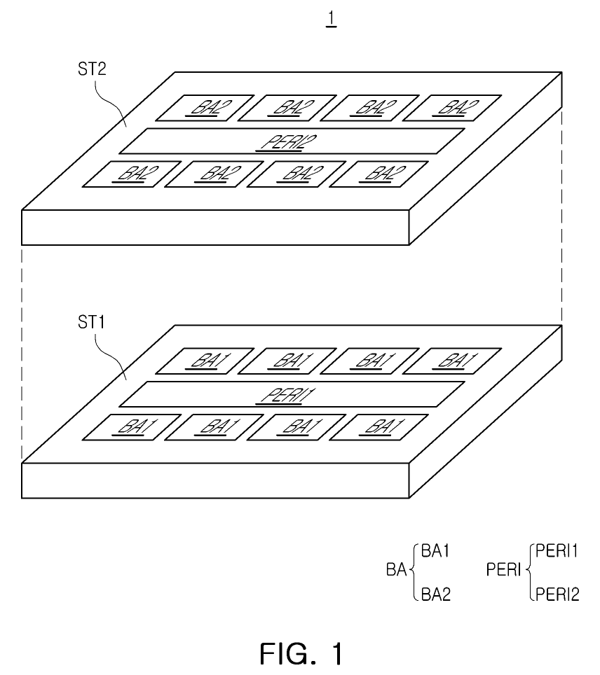

FIG. 1 is a schematic perspective view of a semiconductor device according to an example embodiment.

Referring to FIG. 1, a semiconductor device 1 according to an embodiment may include a first structure ST1 and a second structure ST2 vertically overlapping the first structure ST1. The second structure ST2 may be disposed on the first structure ST1.

In an embodiment, the first structure ST1 may be a first chip structure including memory cells MC, and the second structure ST2 may be a second chip structure including a peripheral circuit capable of operating the memory cells MC. The first structure ST1 and the second structure ST2 may be bonded and formed by a bonding process such as a wafer bonding process. Therefore, the first structure ST1 may be in contact with and bonded to the second structure ST2.

The semiconductor device 1 may include a plurality of banks BA and a peripheral circuit region PERI. The peripheral circuit region PERI may include a first peripheral circuit region PR1 in the first structure ST1 and a second peripheral circuit region PR2 in the second structure ST2. The peripheral circuit region PERI may be a peripheral circuit region in which peripheral circuits for input/output of data or commands, or input of power/ground, are disposed.

Each of the plurality of banks BA may include a first bank region BA1 in the first structure ST1, and a second bank region BA2 in the second structure ST2.

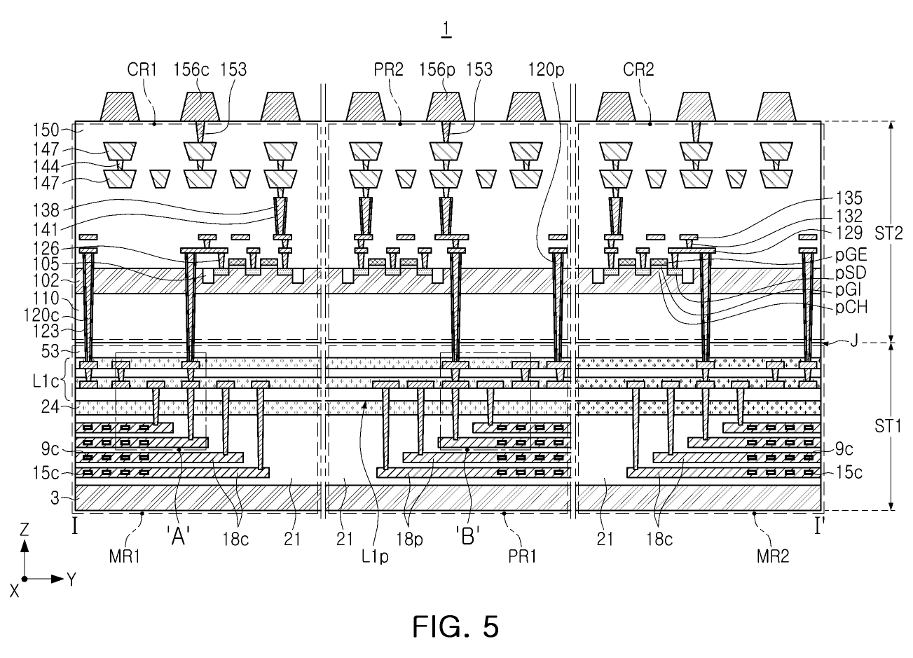

The first bank region BA1 in the first structure ST1 may include memory cell regions MR1 and MR2 (see FIG. 5). The memory cell regions MR1 and MR2 may be disposed in the X-direction and the Y-direction. The X-direction and the Y-direction may be perpendicular to each other. The X-direction and the Y-direction may be referred to as a horizontal direction, and the Z-direction may be referred to as a vertical direction.

The second bank region BA2 in the second structure ST2 may include core circuit regions CR1 and CR2 (see FIG. 5). The core circuit regions CR1 and CR2 may be disposed in the X-direction and the Y-direction. The core circuit regions CR1 and CR2 may overlap the memory cell regions MR1 and MR2 in the vertical direction (Z). The core circuit regions CR1 and CR2 may include a sense amplifier, a sub-word line driver, or the like.

The first peripheral circuit region PR1 and the second peripheral circuit region PR2 may be peripheral circuit regions in which peripheral circuits for input/output of data or commands, or input of power/ground, are disposed, and may include a control circuit capable of controlling the sense amplifier and the sub-word line driver.

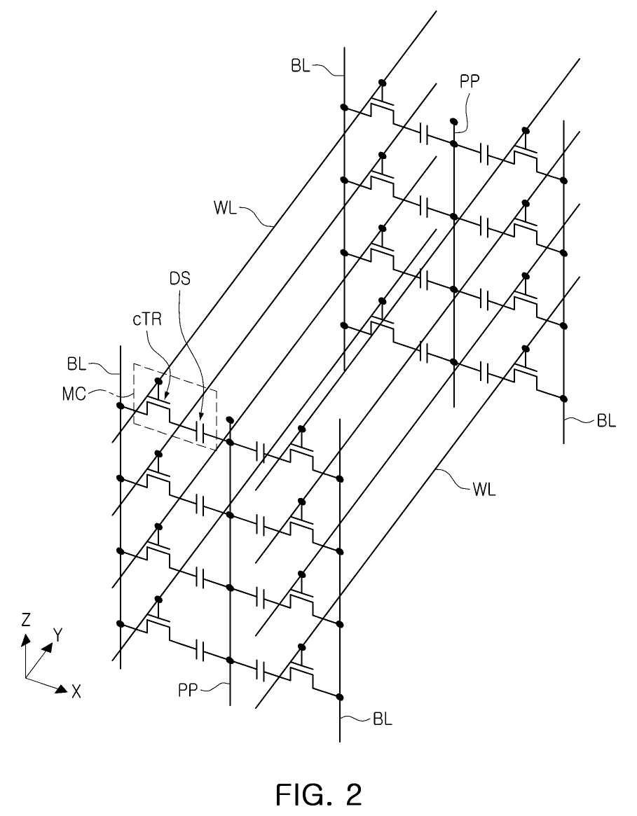

FIG. 2 is a circuit diagram of a memory cell in a memory cell region according to an example embodiment.

Referring to FIG. 2, a memory cell region (MR1 and MR2) may include memory cells MC disposed in the X-direction and the Y-direction, word lines WL connected to the memory cells MC and extending in the Y-direction, and bit lines BL connected to the memory cells MC and extending in the vertical direction.

Each of the memory cells MC may include a cell transistor cTR and an information storage structure DS that may serve as an information storage function. In a memory such as a DRAM, the information storage structure DS may be a cell capacitor that may store information. Adjacent information storage structures DS may share a plate electrode PP. For example, the plate electrode PP may extend in the vertical direction, and may be electrically connected to the information storage structures DS.

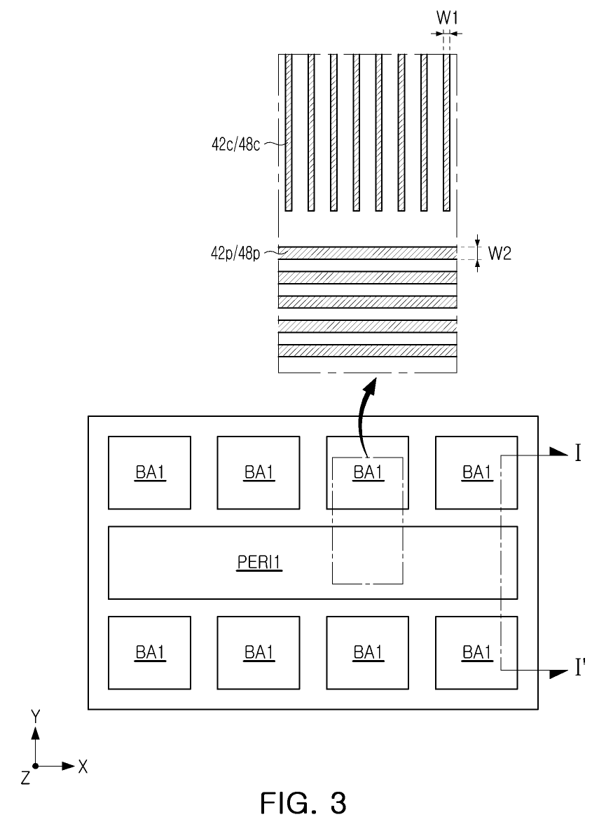

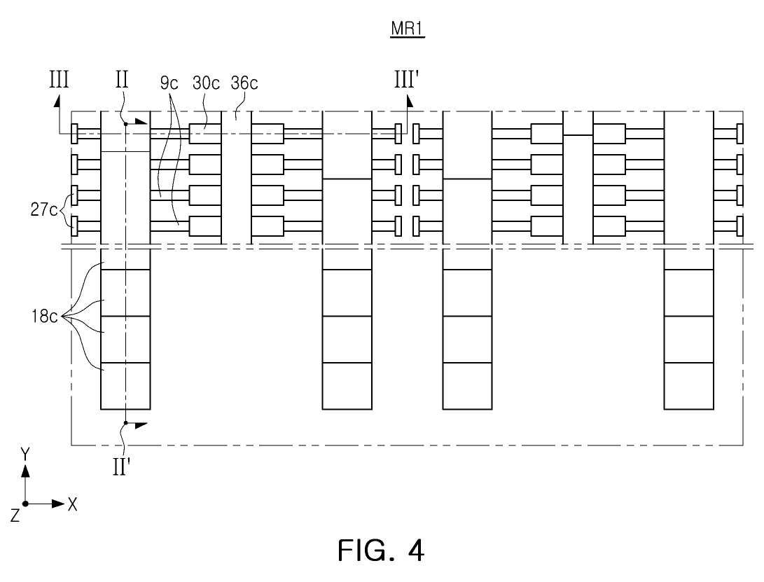

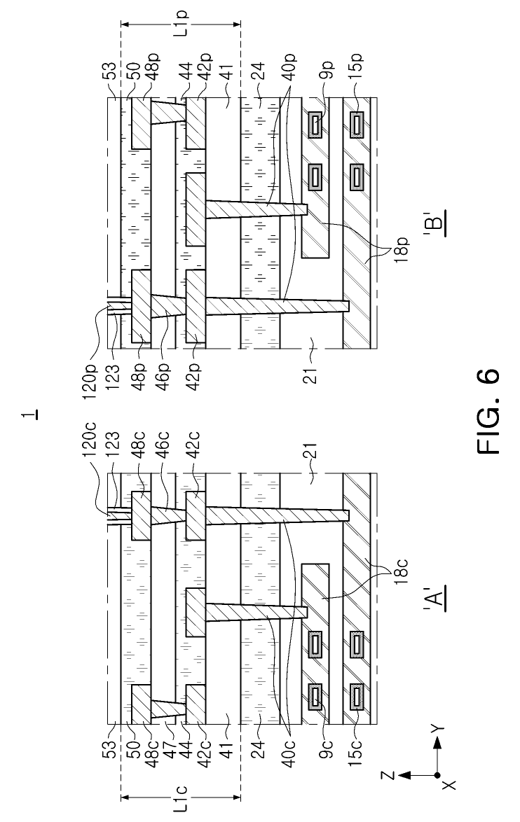

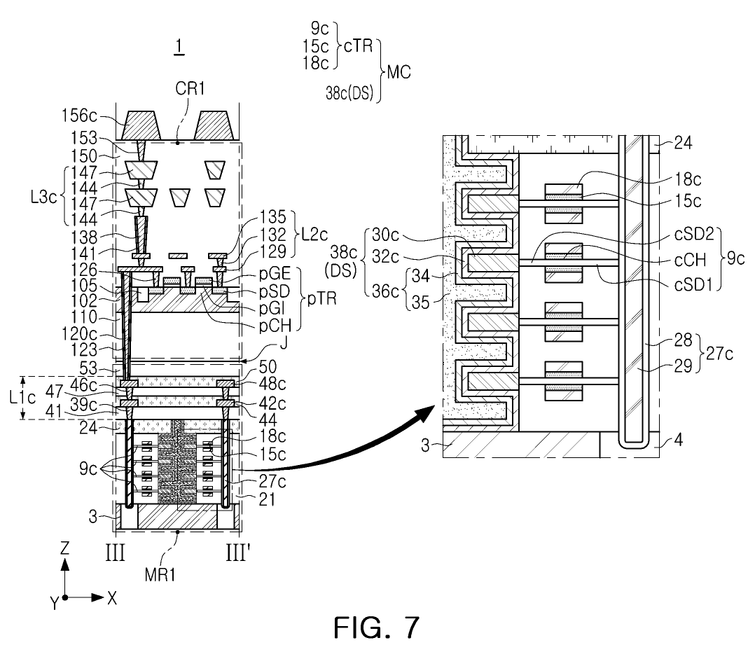

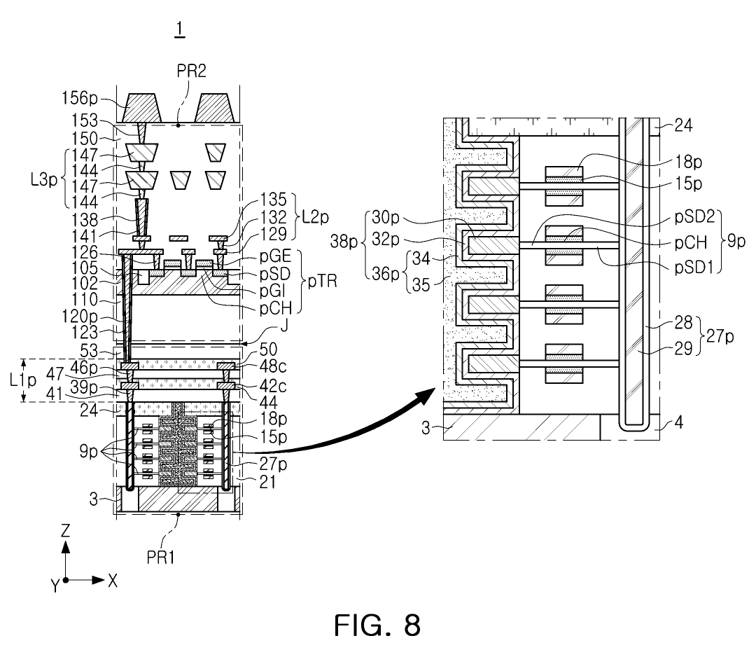

FIG. 3 is a plan view of a first structure. FIG. 4 is a plan view of a first memory cell region of a first structure. FIG. 4 is a plan view of a first memory cell region MR1 of the first bank region BA1 illustrated in FIG. 3. FIG. 5 is a vertical cross-sectional view taken along line I-I’ of the semiconductor device illustrated in FIG. 3. FIG. 5 also illustrates a vertical cross-sectional view taken along line II-II’ of the first memory cell region MR1 illustrated in FIG. 4. FIG. 6 is an enlarged view of a portion of the semiconductor device illustrated in FIG. 5. FIG. 6 corresponds to regions A and B of FIG. 5. FIG. 7 is a vertical cross-sectional view taken along line III-III’ of the memory cell region illustrated in FIG. 4. FIG. 8 is a vertical cross-sectional view of a peripheral circuit region of a semiconductor device according to an example embodiment. FIG. 8 illustrates structures disposed on peripheral circuit regions PR1 and PR2 and corresponding to FIG. 7.

Referring to FIGS. 3-8, a semiconductor device 1 may include a first structure ST1 and a second structure ST2 vertically overlapping the first structure ST1. For example, the semiconductor device 1 may have a peri-on-cell (POC) structure, and the second structure ST2 may be disposed on the first structure ST1.

The first structure ST1 may include memory cell regions MR1 and MR2 and a first peripheral circuit region PR1. The memory cell regions MR1 and MR2 may include a first memory cell region MR1 and a second memory cell region MR2. The first peripheral circuit region PR1 may be spaced apart from the memory cell regions MR1 and MR2 in the horizontal direction, and may be disposed between the memory cell regions MR1 and MR2. As described below, components of the first peripheral circuit region PR1 may be disposed at the same level as corresponding components of the memory cell regions MR1 and MR2. The first peripheral circuit region PR1 may have the same or similar structure as the memory cell regions MR1 and MR2.

The memory cell regions MR1 and MR2 may include a cell transistor cTR and an information storage structure DS, disposed on a first substrate 3. The cell transistor cTR and the information storage structure DS may constitute a memory cell MC described with reference to FIG. 2. The information storage structure DS may be a cell capacitor capable of storing information in a memory such as a DRAM or the like.

The first structure STb may further include a first substrate 3, and cell active patterns 9c and peripheral active patterns 9p, disposed on the first substrate 3. The cell active patterns 9c to be disposed may be disposed on the memory cell regions MR1 and MR2, and the peripheral active patterns 9p may be disposed in the first peripheral circuit region PR1.

The cell active patterns 9c and the peripheral active patterns 9p may be formed of a semiconductor material that may be used as a channel region of a transistor. For example, each of the cell active patterns 9c and the peripheral active patterns 9p may include a semiconductor material, such as a group IV semiconductor, a group III-V compound semiconductor, or a group II-VI compound semiconductor. For example, the group IV semiconductor may include silicon, germanium, or silicon-germanium. Each of the cell active patterns 9c and the peripheral active patterns 9p may include single crystal silicon.

In an embodiment, the cell active patterns 9c and the peripheral active patterns 9p may include an oxide semiconductor, for example, at least one of hafnium-silicon oxide (HSO), hafnium-zinc oxide (HZO), indium-zinc oxide (IZO), indium-gallium oxide (IGO), indium-tin oxide (ITO), indium-gallium-zinc oxide (IGZO), or indium-tin-zinc oxide (ITZO).

In another example, the cell active patterns 9c and the peripheral active patterns 9p may include a two-dimensional (2D) material layer in which atoms may form a predetermined crystal structure, and may form a channel of a transistor. The two-dimensional material layer may include at least one of a transition metal dichalcogenide (TMD) material layer, a black phosphorous material layer, or a hexagonal boron-nitride (hBN) material layer. For example, the two-dimensional material layer may include at least one of BiOSe, Crl, WSe2, MoS2, TaS, WS, SnSe, ReS, β-SnTe, MnO, AsS, P(black), InSe, h-BN, GaSe, GaN, SrTiO, MXene, or Janus 2D materials, which may form a two-dimensional material.

Each of the cell active patterns 9c may include a first source/drain region cSD1 and a second source/drain region cSD2, spaced apart from each other in the X-direction, and a cell channel region cCH between the first and second source/drain regions cSD1 and cSD2.

The first structure ST1 may include cell gate electrodes 18c vertically overlapping the cell channel regions cCH, and cell gate dielectric layers 15c between the cell gate electrodes 18c and the cell channel regions cCH. The cell gate electrodes 18c may be stacked to be spaced apart from each other in the vertical direction (Z). Each of the cell gate electrodes 18c may surround a cell channel region cCH corresponding thereto, among the cell channel regions cCH, in the Y-direction, perpendicular to the X-direction, and may extend in the Y-direction.

The cell transistor cTR described above may include the cell channel region cCH, the first and second source/drain regions cSD1 and cSD2, the cell gate dielectric layer 15c, and the cell gate electrode 18c.

Each of the peripheral active patterns 9p may include a first source/drain region pSD1 and a second source/drain region pSD2, spaced apart from each other in the X-direction, and a peripheral channel region pCH between the first and second source/drain regions pSD1 and pSD2. At least one of the peripheral active patterns 9p may be disposed at the same level as at least one of the cell active patterns 9c.

The first structure ST1 may include peripheral gate electrodes 18p vertically overlapping the peripheral channel regions pCH, and peripheral gate dielectric layers 15p between the peripheral gate electrodes 18p and the peripheral channel regions pCH. The peripheral gate electrodes 18p may be stacked to be spaced apart from each other in the vertical direction (Z). Each of the peripheral gate electrodes 18p may surround a peripheral channel region pCH corresponding thereto, among the peripheral channel regions pCH, in the Y-direction, perpendicular to the X-direction, and may extend in the Y-direction. At least one of the peripheral gate electrodes 18p may be disposed at the same level as at least one of the cell gate electrodes 18c.

The cell gate electrodes 18c and the peripheral gate electrodes 18p may include a conductive material, and the conductive material may include at least one of a doped semiconductor material (e.g., doped silicon, doped germanium, or the like), a conductive metal nitride (e.g., titanium nitride, tantalum nitride, tungsten nitride, or the like), a metal (e.g., tungsten, titanium, tantalum, cobalt, aluminum, ruthenium, or the like), or a metal-semiconductor compound (e.g., tungsten silicide, cobalt silicide, titanium silicide, or the like).

The cell gate dielectric layer 15c and the peripheral gate dielectric layer 15p may include at least one of silicon oxide, silicon nitride, a low-κ material, or a high-κ material. The high-κ material may mean a dielectric material having a higher dielectric constant than silicon oxide, and the low-κ material may mean a dielectric material having a lower dielectric constant than silicon oxide. The high-κ material may be, for example, a metal oxide or a metal oxynitride. The high-κ material may be, for example, any one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃). The cell gate dielectric layer 15c may be formed as a single layer or a plurality of layers of the materials described above.

The information storage structure DS described above may be an information storage structure 38c including a first electrode 30c, a dielectric layer 32c, and a second electrode 36c. The first electrode 30c may be connected to a second source/drain region cSD2 corresponding thereto, among the second source/drain regions cSD2. The first electrode 30c may have a pillar shape extending in the X-direction. The dielectric layer 32c may extend between the first electrode 30c and the second electrode 36c. The second electrode 36c may cover the dielectric layer 32c. The second electrode 36c may include a first electrode material layer 34 contacting the dielectric layer 32c, and a second electrode material layer 35 contacting the first electrode material layer 34. The second electrodes 36c of the information storage structures DS may be plate electrodes PP connected to each other.

In the information storage structures DS, a lower surface of each of the second electrodes 36c may be disposed at a lower level than a lowermost cell transistor among the cell transistors cTR, and the upper surface of each of the second electrodes 36c may be disposed at a higher level than an uppermost cell transistor among the cell transistors cTR. Each of the second electrodes 36c may extend in the Y-direction.

The memory cells MC including the cell transistors cTR and the information storage structures DS may be disposed three-dimensionally in the vertical direction (Z), the X-direction, and the Y-direction, perpendicular to each other.

The first structure ST1 may further include a structure (30p, 32p, and 36p) disposed in the first peripheral circuit region PR1. The structure (30p, 32p, and 36p) may include a first electrode 30p, a dielectric layer 32p, and a second electrode 36p.

The first electrode 30p may be connected to a second source/drain region pSD2 corresponding thereto, among the second source/drain regions pSD2. The first electrode 30p may have a pillar shape extending in the X-direction. The dielectric layer 32p may extend between the first electrode 30p and the second electrode 36p. The second electrode 36p may cover the dielectric layer 32p. The second electrode 36p may include a first electrode material layer 34 contacting the dielectric layer 32p and a second electrode material layer 35 contacting the first electrode material layer 34.

In an embodiment, a memory cell MC may be disposed in the first peripheral circuit region PR1. For example, the peripheral channel region pCH, the first and second source/drain regions pSD1 and pSD2, the peripheral gate dielectric layer 15p and the peripheral gate electrode 18p may function as a cell transistor cTR. The structure (30p, 32p, and 36p) may be the information storage structure DS described with reference to FIG. 2. The second electrodes 36p of the information storage structures DS may be plate electrodes PP connected to each other.

In an embodiment, a CMOS transistor may be disposed in the first peripheral circuit region PR1. For example, the first source/drain regions pSD1 and the second source/drain regions pSD2 of the peripheral active patterns 9p may be doped with N-type impurities or P-type impurities. The CMOS transistor may be used in a peripheral circuit for input/output of data or commands, or input of power/ground.

The first structure ST1 may further include cell bit lines 27c disposed in the memory cell regions MR1 and MR2 and contacting the cell active patterns 9c. The cell bit lines 27c may extend in the vertical direction (Z), and may be spaced apart from each other in the X-direction and the Y-direction. Each of the cell bit lines 27c may be in contact with the first source/drain regions cSD1 of the cell active patterns 9c. The cell bit lines 27c may correspond to the bit lines BL described with reference to FIG. 2.

The first structure ST1 may further include peripheral bit lines 27p disposed in the first peripheral circuit region PR1 and contacting the peripheral active patterns 9p. The peripheral bit lines 27p may extend in the vertical direction (Z), and may be spaced apart from each other in the X-direction and the Y-direction. Each of the peripheral bit lines 27p may be in contact with the first source/drain regions pSD1 of the peripheral active patterns 9p.

Each of the cell bit lines 27c and the peripheral bit lines 27p may include a pillar pattern 29 and a conductive liner 28 covering a side surface and a lower surface of the pillar pattern 29. The conductive liner 28 may include at least one of doped polysilicon or a metal nitride.

The first structure ST1 may further include an insulating layer 4 disposed in the first substrate 3. The cell bit lines 27c and the peripheral bit lines 27p may partially penetrate the insulating layer 4, and lower ends of the cell bit lines 27c and the peripheral bit lines 27p may be disposed at a level lower than an upper surface of the insulating layer 4.

The first structure ST1 may further include an interlayer insulating layer 21, a first capping insulating layer 24, a first insulating layer 41, a second capping insulating layer 44, a second insulating layer 47, and a third capping insulating layer 50, sequentially disposed on the first substrate 3. The interlayer insulating layer 21 may cover cell transistors cTR in the memory cell regions MR1 and MR2. The interlayer insulating layer 21 may also be disposed in the first peripheral circuit region PR1, and may cover components corresponding to the cell transistors cTR.

The first capping insulating layer 24 may be disposed on the interlayer insulating layer 21, and a portion of the cell bit line 27c and a portion of the information storage structure 38c may penetrate the first capping insulating layer 24. For example, an upper surface of the cell bit line 27c and an upper surface of the information storage structure 38c may be coplanar with the first capping insulating layer 24.

The interlayer insulating layer 21, the first capping insulating layer 24, the first insulating layer 41, the second capping insulating layer 44, the second insulating layer 47, and the third capping insulating layer 50 may include an insulating material, for example, at least one of silicon nitride, silicon oxynitride, or silicon oxycarbide. The first capping insulating layer 24, the second capping insulating layer 44, and the third capping insulating layer 50 may include silicon nitride.

The first structure ST1 may further include a first cell interconnection layer 42c, a cell via 46c, and a second cell interconnection layer 48c, disposed in the memory cell regions MR1 and MR2. The first cell interconnection layer 42c may be disposed on the first insulating layer 41, and may be covered by the second capping insulating layer 44. The second cell interconnection layer 48c may be disposed on the second insulating layer 47, and may be covered by the third capping insulating layer 50. The cell via 46c may extend in the vertical direction, and may connect at least one of the first cell interconnection layers 42c to a second cell interconnection layer 48c corresponding thereto. The first insulating layer 41, the first cell interconnection layer 42c, the second capping insulating layer 44, the cell via 46c, the second insulating layer 47, the second cell interconnection layer 48c, and the third capping insulating layer 50 may constitute a cell interconnection structure L1c. The cell interconnection structure L1c may be electrically connected to at least one of the cell gate electrodes 18c or the cell bit lines 27c.

The first structure ST1 may further include cell contact structures 39c and 40c disposed in the memory cell regions MR1 and MR2. The cell contact structures 39c and 40c may connect the cell transistors cTR to the cell interconnection structure L1c. For example, the cell contact structures 39c may connect at least one of the cell bit lines 27c to a first cell interconnection layer 42c corresponding thereto. The cell contact structures 40c may connect at least one of the cell gate electrodes 18c to a first cell interconnection layer 42c corresponding thereto.

The first structure ST1 may further include a first peripheral interconnection layer 42p, a peripheral via 46p, and a second peripheral interconnection layer 48p, disposed in the first peripheral circuit region PR1. The first peripheral interconnection layer 42p may be disposed on the first insulating layer 41, and may be covered by the second capping insulating layer 44. The second peripheral interconnection layer 48p may be disposed on the second insulating layer 47, and may be covered by the third capping insulating layer 50. The peripheral via 46p may extend in the vertical direction, and may connect at least one of the first peripheral interconnection layers 42p to a second peripheral interconnection layer 48p corresponding thereto. The first insulating layer 41, the first peripheral interconnection layer 42p, the second capping insulating layer 44, the peripheral via 46p, the second insulating layer 47, the second peripheral interconnection layer 48p, and the third capping insulating layer 50 may constitute a peripheral interconnection structure L1p. The peripheral interconnection structure L1p may be electrically connected to at least one of the peripheral gate electrodes 18p and the peripheral bit lines 27p.

The peripheral interconnection structure L1p may be disposed at the same level as the cell interconnection structure L1c. For example, the first peripheral interconnection layer 42p, the peripheral via 46p, and the second peripheral interconnection layer 48p may be disposed at the same level as the first cell interconnection layer 42c, the cell via 46c, and the second cell interconnection layer 48c, respectively. The peripheral interconnection structure L1p may be used to transmit an input/output signal or a power/ground signal to a transistor, which may be composed of the peripheral channel region pCH, the first and second source/drain regions pSD1 and pSD2, the peripheral gate dielectric layer 15p, and the peripheral gate electrode 18p. In an embodiment, the peripheral interconnection structure L1p may be electrically connected to the cell interconnection structure L1c, and may be used to transmit an input/output signal or a power/ground signal to the cell transistor cTR.

As compared to a case in which dummy lines are disposed at the same level as the cell interconnection structure L1c in the first peripheral circuit region PR1, in embodiments of the present disclosure, when the peripheral interconnection structure L1p is disposed at the same level as the cell interconnection structure L1c, the number of interconnection layers of the semiconductor device 1 may be reduced. Therefore, a size of the semiconductor device 1 may be reduced, and a more compact semiconductor device 1 may be implemented.

Referring to FIGS. 3, 5, and 6, a horizontal width of the first peripheral interconnection layer 42p and a horizontal width of the second peripheral interconnection layer 48p according to embodiments of the present disclosure may be greater than a horizontal width of the first cell interconnection layer 42c and a horizontal width of the second cell interconnection layer 48c, respectively. For example, as illustrated in FIG. 3, the first cell interconnection layer 42c and the second cell interconnection layer 48c may have a first horizontal width W1, and the first peripheral interconnection layer 42p and the second peripheral interconnection layer 48p may have a second horizontal width W2, greater than the first horizontal width W1. Therefore, resistance of the peripheral interconnection structure L1p may be reduced, and RC delay of the semiconductor device 1 may be reduced. In an embodiment, a horizontal width of the peripheral via 46p may be greater than a horizontal width of the cell via 46c.

The first structure ST1 may further include peripheral contact structures 39p and 40p disposed in the first peripheral circuit region PR1. The peripheral contact structures 39p and 40p may connect a transistor, which may be composed of the peripheral active pattern 9p, the peripheral gate dielectric layer 15p, and the peripheral gate electrode 18p, to the peripheral interconnection structure L1p. For example, the peripheral contact structures 39p may connect at least one of the peripheral bit lines 27p to a first peripheral interconnection layer 42p corresponding thereto. The peripheral contact structures 40p may connect at least one of the peripheral gate electrodes 18p to a first peripheral interconnection layer 42p corresponding thereto.

The first structure ST1 may further include a first bonding layer 53 disposed on the cell interconnection structure L1c and on the peripheral interconnection structure L1p. An upper surface of the first bonding layer 53 may correspond to a bonding surface J between the first structure ST1 and the second structure ST2.

The second structure ST2 may include core circuit regions CR1 and CR2 and a second peripheral circuit region PR2. The core circuit regions CR1 and CR2 may include a first core circuit region CR1 and a second core circuit region CR2, spaced from each other in the horizontal direction. The second peripheral circuit region PR2 may be spaced from the core circuit regions CR1 and CR2 in the horizontal direction, and may be disposed between the core circuit regions CR1 and CR2. The core circuit regions CR1 and CR2 may overlap the memory cell regions MR1 and MR2 in the vertical direction, and the second peripheral circuit region PR2 may overlap the first peripheral circuit region PR1 in the vertical direction.

The second structure ST2 may further include a second substrate 102 including peripheral channel regions pCH, and a device isolation region 105 defining the peripheral channel regions pCH on the second substrate 102. The device isolation region 105 may define side surfaces of the peripheral channel regions pCH. The device isolation region 105 may be formed of an insulating material.

The second substrate 102 may include a semiconductor material, for example, a group IV semiconductor, a group III-V compound semiconductor, or a group II-VI compound semiconductor. For example, the group IV semiconductor may include silicon, germanium, or silicon-germanium. The second substrate 102 may include single crystal silicon.

The second structure ST2 may further include a peripheral circuit transistor pTR disposed on the second substrate 102.

The peripheral circuit transistor pTR may include peripheral source/drain regions pSD formed in the peripheral channel region pCH, a peripheral channel region pCH between the peripheral source/drain regions pSD, and a peripheral gate (pGI and pGE) on the peripheral channel region pCH. The peripheral gate (pGI and pGE) may include a peripheral gate dielectric layer pGI and a peripheral gate electrode pGE on the peripheral gate dielectric layer pGI. The peripheral circuit transistors pTR may be disposed in the core circuit regions CR1 and CR2 and the second peripheral circuit region PR2.

As illustrated in FIG. 5, according to embodiments of the present disclosure, the first peripheral circuit region PR1 may be disposed in the first structure ST1 in which the memory cell regions MR1 and MR2 are disposed. Therefore, as compared to a semiconductor device in which the first peripheral circuit region PR1 is not disposed in the first structure ST1, an area of the peripheral circuit region (PR1 and PR2) may be reduced by an area of the first peripheral circuit region PR1. Therefore, a size of the semiconductor device 1 may be reduced.

The second structure ST2 may further include a second bonding layer 110 disposed below the second substrate 102. A lower surface of the second bonding layer 110 may correspond to the bonding surface J between the first structure ST1 and the second structure ST2. For example, the second bonding layer 110 may be bonded to the first bonding layer 53.

The second structure ST2 may include contacts 126, interconnection layers 129, vias 132, and interconnection layers 135, disposed on the second substrate 102. The contacts 126 may extend in the vertical direction, and may be connected to the peripheral source/drain regions pSD. The interconnection layers 129 may be disposed on the peripheral circuit transistor pTR, and may be electrically connected to the peripheral circuit transistor pTR. For example, at least one of the interconnection layers 129 may be connected to the peripheral source/drain regions pSD. The interconnection layers 135 may be disposed on the interconnection layers 129, and the vias 132 may connect the interconnection layers 129 and the interconnection layers 135.

The interconnection layers 129, the vias 132, and the interconnection layers 135 disposed in the core circuit regions CR1 and CR2 may form a first lower interconnection structure L2c. The interconnection layers 129, the vias 132, and the interconnection layers 135 disposed in the second peripheral circuit region PR2 may form a second lower interconnection structure L2p. For example, the first lower interconnection structure L2c may be electrically connected to the peripheral circuit transistor pTR disposed in the core circuit regions CR1 and CR2, and the second lower interconnection structure L2p may be electrically connected to the peripheral circuit transistor pTR disposed in the second peripheral circuit region PR2.

The semiconductor device 1 may further include a cell through-via 120c and a peripheral through-via 120p. The cell through-via 120c may penetrate the second substrate 102 in the vertical direction, and may be electrically connected to the first lower interconnection structure L2c. The peripheral through-via 120p may penetrate the second substrate 102 in the vertical direction, and may be electrically connected to the second lower interconnection structure L2p. The cell through-via 120c and the peripheral through-via 120p may have a tapered shape. A horizontal width of the cell through-via 120c and a horizontal width of the peripheral through-via 120p may be changed toward the first structure ST1. For example, the horizontal width of the cell through-via 120c and the horizontal width of the peripheral through-via 120p may decrease toward the first structure ST1.

In an embodiment, the cell through-via 120c and the peripheral through-via 120p may penetrate the bonding surface J. For example, the cell through-via 120c may penetrate the first bonding layer 53 and the second bonding layer 110 in the vertical direction, and may be electrically connected to the cell interconnection structure L1c. The cell through-via 120c may be in contact with the second cell interconnection layer 48c of the cell interconnection structure L1c. The peripheral through-via 120p may be in contact with the peripheral interconnection structure L1p by penetrating the first bonding layer 53 and the second bonding layer 110 in the vertical direction. The peripheral through-via 120p may be in contact with the second peripheral interconnection layer 48p of the peripheral interconnection structure L1p.

The second structure ST2 may further include insulating spacers 123 covering a side surface of the cell through-via 120c and a side surface of the peripheral through-via 120p. The insulating spacers 123 may electrically insulate the cell through-via 120c and the peripheral through-via 120p from the second substrate 102.

The second structure ST2 may further include connecting vias 138, insulating spacers 141, vias 144, and interconnection layers 147, on the first lower interconnection structure L2c and the second lower interconnection structure L2p. The connecting vias 138 may be in contact with the first lower interconnection structure L2c and the second lower interconnection structure L2p, and may extend in the vertical direction. The insulating spacers 141 may cover side surfaces of the connecting vias 138.

The interconnection layers 147 may be composed as a plurality of layers, and the vias 144 may electrically connect the interconnection layers 147 spaced apart in the vertical direction. The vias 144 and the interconnection layers 147 disposed in the core circuit regions CR1 and CR2 may form a first upper interconnection structure L3c. The vias 144 and the interconnection layers 147 disposed in the second peripheral circuit region PR2 may form a second upper interconnection structure L3p. The first upper interconnection structure L3c and the second upper interconnection structure L3p may be electrically connected to the first lower interconnection structure L2c and the second lower interconnection structure L2p, respectively, through the connecting vias 138.

The second structure ST2 may further include an interlayer insulating layer 150 and vias 153. The interlayer insulating layer 150 may cover the second substrate 102, the peripheral circuit transistor pTR, the first lower interconnection structure L2c, the second lower interconnection structure L2p, the first upper interconnection structure L3c, and the second upper interconnection structure L3p. The vias 153 may be disposed on and in contact with the first upper interconnection structure L3c and the second upper interconnection structure L3p.

The second structure ST2 may further include first input/output pads 156c and second input/output pads 156p on the interlayer insulating layer 150. The first input/output pads 156c may be disposed in the core circuit regions CR1 and CR2, and may be electrically connected to the cell interconnection structure L1c through the first upper interconnection structure L3c, the first lower interconnection structure L2c, and the cell through-via 120c. The second input/output pads 156p may be disposed in the second peripheral circuit region PR2, and may be electrically connected to the peripheral interconnection structure L1p through the second upper interconnection structure L3p, the second lower interconnection structure L2p, and the peripheral through-via 120p.

According to embodiments of the present disclosure, as described above, the peripheral interconnection structure L1p may be disposed at the same level as the cell interconnection structure L1c in the first peripheral circuit region PR1. Therefore, the peripheral interconnection structure L1p may function as a power delivery network, and may reduce a power delivery path from the second input/output pads 156p to the components 9p, 15p, and 18p in the first peripheral circuit region PR1.

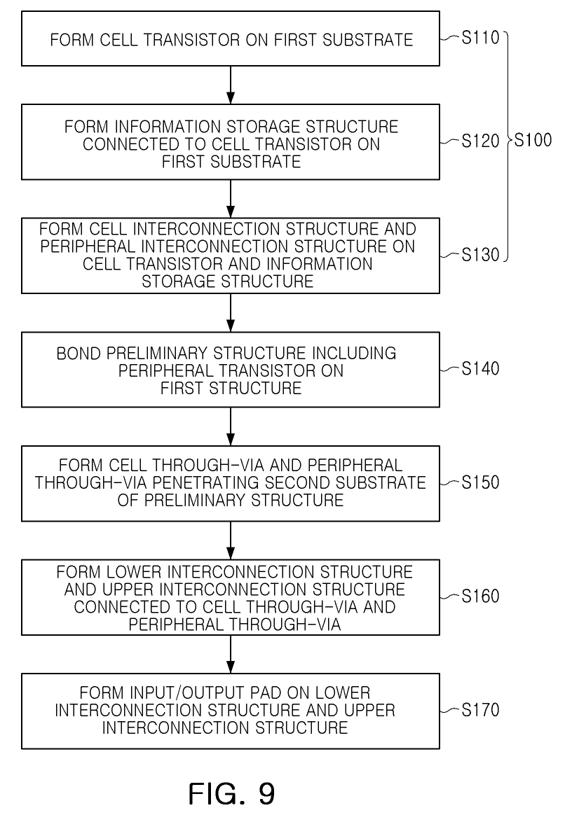

FIG. 9 is a flow chart of a method for manufacturing a semiconductor device according to an example embodiment.

Referring to FIG. 9, a method for manufacturing a semiconductor device according to an example embodiment may include forming a first structure (S100), bonding a preliminary structure including a peripheral transistor on the first structure (S140), forming a cell through-via and a peripheral through-via penetrating a second substrate of the preliminary structure (S150), forming a lower interconnection structure and an upper interconnection structure connected to the cell through-via and the peripheral through-via (S160), and forming an input/output pad on the lower interconnection structure and the upper interconnection structure (S170). Forming the first structure (S100) may include forming a cell transistor on the first substrate (S110), forming an information storage structure connected to the cell transistor on the first substrate (S120), and forming a cell interconnection structure and a peripheral interconnection structure on the cell transistor and the information storage structure (S130).

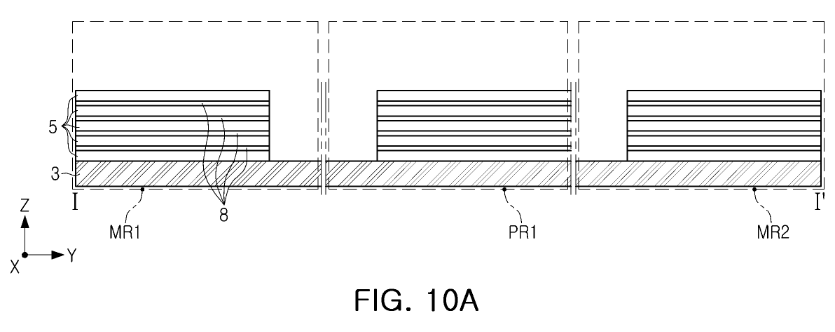

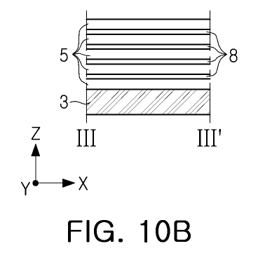

FIGS. 10A-16B are plan views and vertical cross-sectional views illustrating a method for manufacturing a semiconductor device according to an example embodiment according to a process sequence.

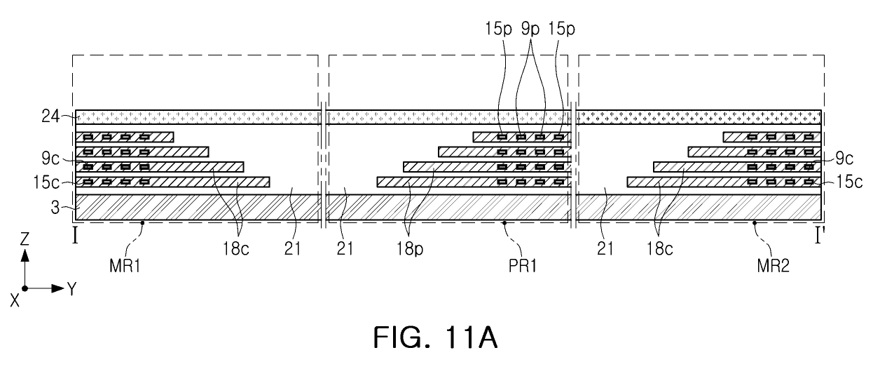

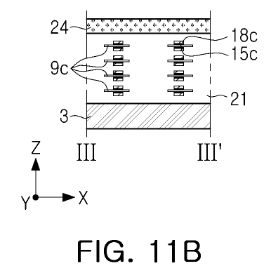

FIGS. 10A-11B illustrate forming a cell transistor on a first substrate (S110).

Referring to FIGS. 10A and 10B, a stack structure (5 and 8) may be formed on a first substrate 3. The stack structure (5 and 8) may be formed in a memory cell region (MR1 and MR2) and a first peripheral circuit region PR1. The stack structure (5 and 8) may include sacrificial semiconductor layers 5 and channel semiconductor layers 8, alternately stacked.

Referring to FIGS. 11A and 11B, the stack structure (5 and 8) may be patterned to form cell active patterns 9c formed by patterning the channel semiconductor layers 8.

Cell transistors cTR may be formed in the memory cell region (MR1 and MR2). For example, a structure buried by an interlayer insulating layer 21, and including cell gate electrodes 18c surrounding the cell active patterns 9c, and cell gate dielectric layers 15c between the cell gate electrodes 18c and the cell active patterns 9c, may be formed. The cell gate dielectric layers 15c and the cell gate electrodes 18c, surrounding the cell active patterns 9c, may constitute cell transistors cTR.

In the first peripheral circuit region PR1, a structure buried by an interlayer insulating layer 21, and including peripheral gate electrodes 18p surrounding the peripheral active patterns 9p and peripheral gate dielectric layers 15p between the peripheral gate electrodes 18p and the peripheral active patterns 9p, may be formed at the same level as the cell transistors cTR. A first capping insulating layer 24 may be formed on the interlayer insulating layer 21.

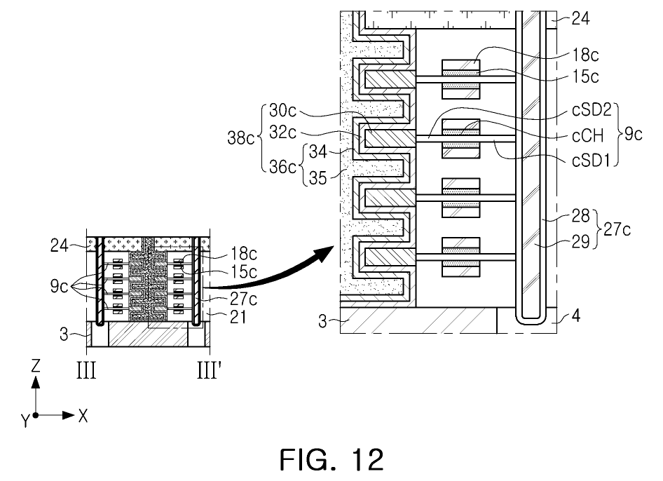

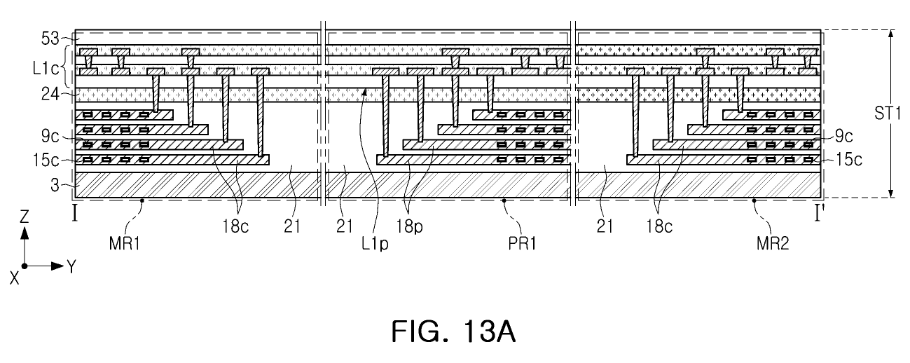

Referring to FIG. 12, a cell bit line 27c and an information storage structure DS, connected to the cell transistor cTR, may be formed on the first substrate 3 (S120).

The information storage structures DS may be formed in the memory cell regions MR1 and MR2. The information storage structures DS may penetrate the first capping insulating layer 24 and the interlayer insulating layer 21. Each of the information storage structures DS may be an information storage structure 38c including a first electrode 30c connected to a cell active pattern 9c corresponding thereto, among the cell active patterns 9c, a second electrode 36c covering the first electrode 30c, and a dielectric layer 32c between the first electrode 30c and the second electrode 36c. The cell transistors cTR and the information storage structures DS may constitute memory cells MC.

The cell bit lines 27c may be formed in the memory cell regions MR1 and MR2. The cell bit lines 27c may penetrate the first capping insulating layer 24 and the interlayer insulating layer 21. Each of the cell bit lines 27c may be connected to a cell active pattern 9c corresponding thereto, among the cell active patterns 9c. Each of the cell bit lines 27c may include a pillar pattern 29 and a conductive liner 28 covering a side surface and a lower surface of the pillar pattern 29.

According to an embodiment, peripheral bit lines 27p and the information storage structures DS may also be formed in the first peripheral circuit region PR1 as illustrated in FIG. 8.

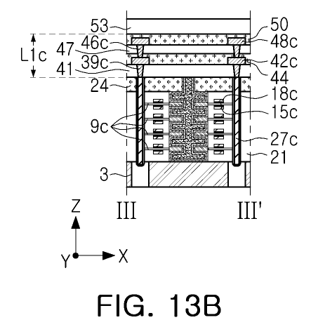

Referring to FIGS. 13A and 13B, a cell interconnection structure L1c and a peripheral interconnection structure L1p may be formed on the information storage structure DS (S130).

For example, a first insulating layer 41, a first cell interconnection layer 42c, a second capping insulating layer 44, a cell via 46c, a second insulating layer 47, a second cell interconnection layer 48c, and a third capping insulating layer 50 may be formed on the first capping insulating layer 24. The first insulating layer 41, the first cell interconnection layer 42c, the second capping insulating layer 44, the cell via 46c, the second insulating layer 47, the second cell interconnection layer 48c, and the third capping insulating layer 50 may constitute a cell interconnection structure L1c. Before forming the cell interconnection structure L1c, cell contact structures 39c and 40c may be formed. The cell contact structures 39c and 40c may connect the cell transistors cTR to the cell interconnection structure L1c.

In an embodiment, a peripheral interconnection structure L1p may be formed simultaneously with the cell interconnection structure L1c in the first peripheral circuit region PR1. For example, a first peripheral interconnection layer 42p, a peripheral via 46p, and a second peripheral interconnection layer 48p may be formed at the same level as the first cell interconnection layer 42c, the cell via 46c, and the second cell interconnection layer 48c, respectively. A first insulating layer 41, the first peripheral interconnection layer 42p, a second capping insulating layer 44, the peripheral via 46p, a second insulating layer 47, the second peripheral interconnection layer 48p, and a third capping insulating layer 50 may constitute a peripheral interconnection structure L1p. Before the first insulating layer 41 is formed and the first cell interconnection layer 42c and the first peripheral interconnection layer 42p are formed, the cell contact structures 39c and 40c and peripheral contact structures 39p and 40p may be formed.

A first structure ST1 may be formed by forming a first bonding layer 53 on the third capping insulating layer 50.

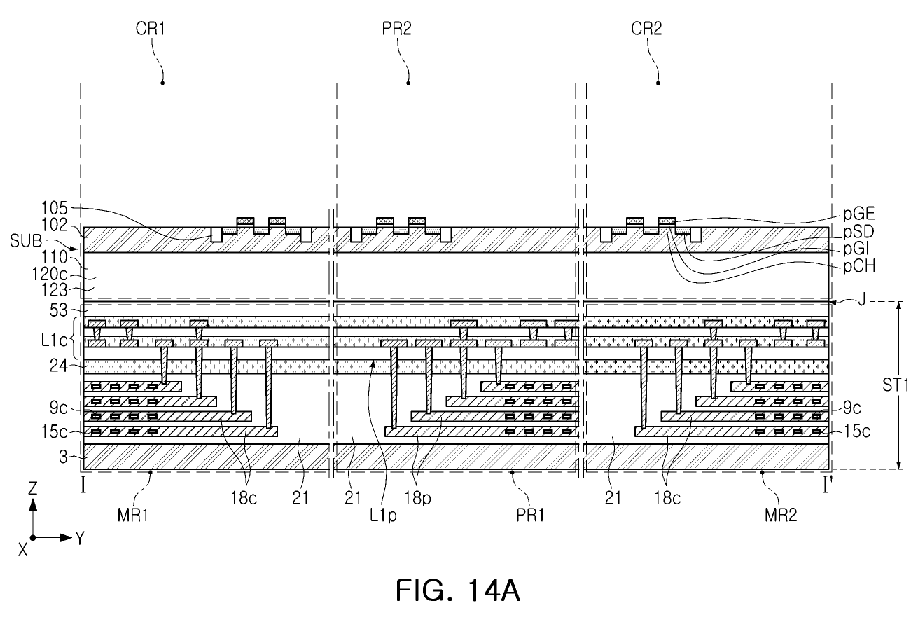

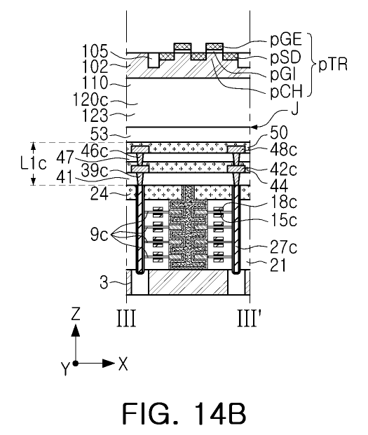

Referring to FIGS. 14A and 14B, a preliminary structure SUB including a peripheral transistor pTR may be bonded on the first structure ST1 (S140). The preliminary structure SUB may include a second substrate 102, a peripheral transistor pTR on the second substrate 102, and a second bonding layer 110 below the second substrate 102. The second bonding layer 110 may be bonded to the first bonding layer 53.

The peripheral circuit transistor pTR may include peripheral source/drain regions pSD formed in the peripheral channel region pCH, a peripheral channel region pCH between the peripheral source/drain regions pSD, and a peripheral gate (pGI and pGE) on the peripheral channel region pCH. The peripheral gate (pGI and pGE) may include a peripheral gate dielectric layer pGI and a peripheral gate electrode pGE on the peripheral gate dielectric layer pGI. The second structure ST2 may further include a device isolation region 105 defining the peripheral channel regions pCH on the second substrate 102.

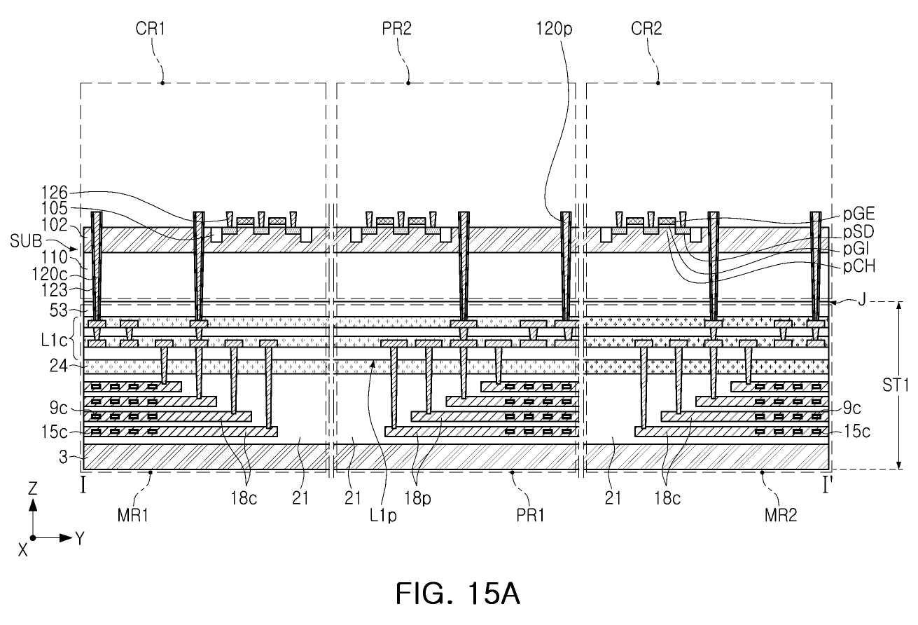

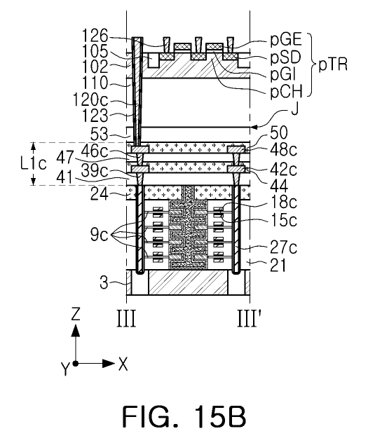

Referring to FIGS. 15A and 15B, a cell through-via 120c and a peripheral through-via 120p penetrating the second substrate 102 of the preliminary structure SUB may be formed (S150). The cell through-via 120c and the peripheral through-via 120p may be formed in the core circuit region CR1 and CR2 and the second peripheral circuit region PR2, respectively. The cell through-via 120c and the peripheral through-via 120p may penetrate the bonding surface J between the second bonding layer 110 and the first bonding layer 53, and the cell through-via 120c and the peripheral through-via 120p may be connected to the cell interconnection structure L1c and the peripheral interconnection structure L1p, respectively. Contacts 126 connected to the peripheral source/drain regions pSD of the peripheral circuit transistor pTR may be formed simultaneously with the cell through-via 120c and the peripheral through-via 120p.

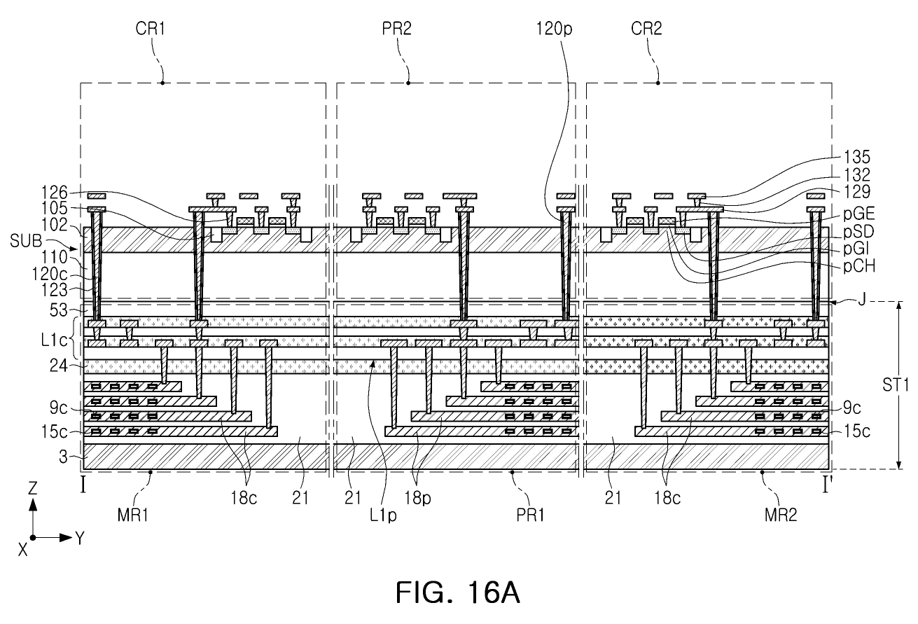

Referring to FIGS. 16A and 16B, lower interconnection structures L2c and L2p connected to the cell through-via 120c and the peripheral through-via 120p may be formed. A first lower interconnection structure L2c may be formed in a core circuit region (CR1 and CR2) by forming interconnection layers 129, vias 132, and interconnection layers 135 on the peripheral circuit transistor pTR. A second lower interconnection structure L2p including interconnection layers 129, vias 132, and interconnection layers 135 may be formed in a second peripheral circuit region PR2.

Referring again to FIGS. 3-8, upper interconnection structures L3c and L3p may be formed on the lower interconnection structures L2c and L2p (S160). The upper interconnection structures L3c and L3p may be composed of vias 144 and interconnection layers 147. A first upper interconnection structure L3c may be formed in the core circuit region (CR1 and CR2), and a second upper interconnection structure L3p may be formed in the second peripheral circuit region PR2.

Thereafter, vias 153 and an interlayer insulating layer 150 may be formed on the upper interconnection structures L3c and L3p, and input/output pads 156c and 156p connected to the upper interconnection structures L3c and L3p may be formed (S170) to form a second structure ST2, thereby manufacturing a semiconductor device 1.

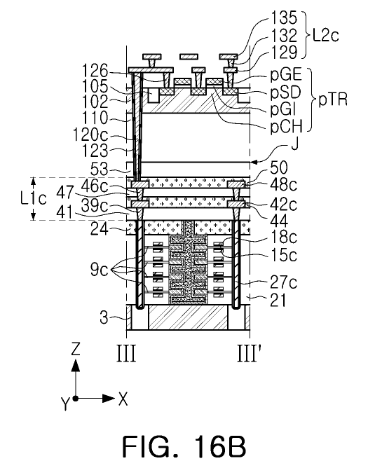

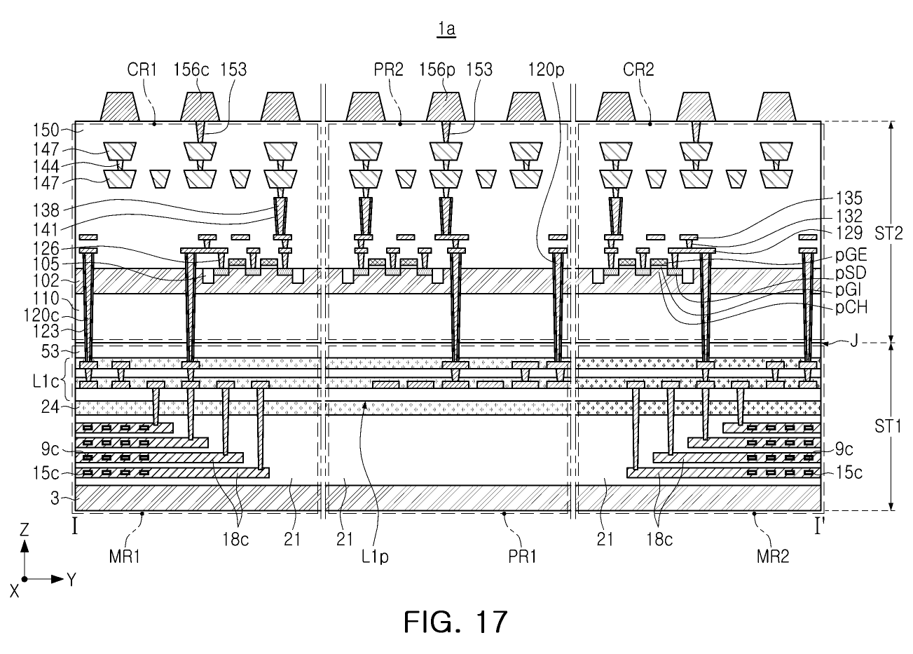

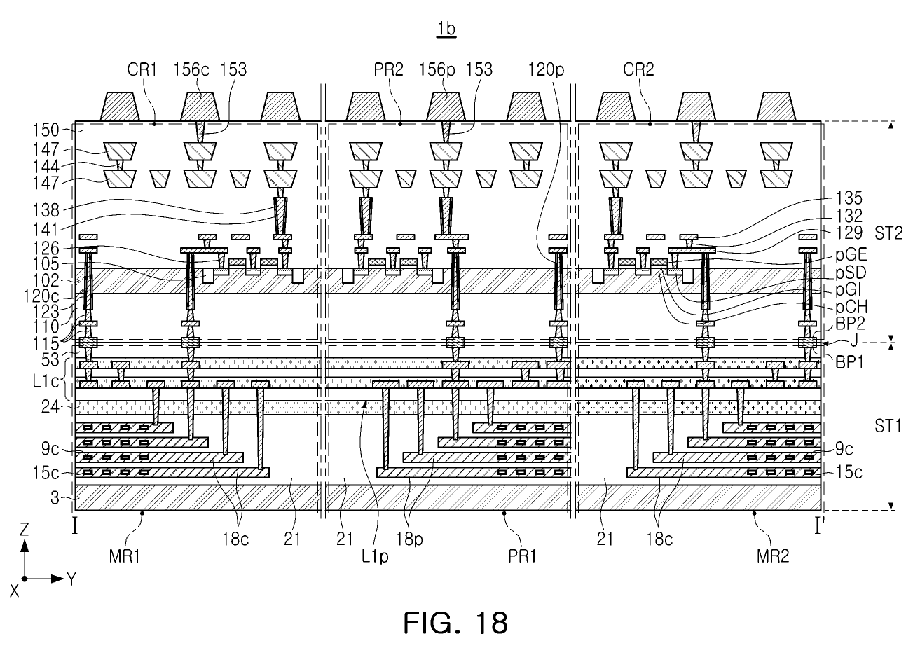

FIGS. 17 and 18 are vertical cross-sectional views of semiconductor devices according to example embodiments.

Referring to FIG. 17, a semiconductor device 1a may include a peripheral interconnection structure L1p disposed at the same level as a cell interconnection structure L1c. In an embodiment, unlike the semiconductor device 1, a transistor including a peripheral active pattern 9p, a peripheral gate dielectric layer 15p, and a peripheral gate electrode 18p may be omitted.

Referring to FIG. 18, a semiconductor device 1b may include a peripheral interconnection structure L1p disposed at the same level as a cell interconnection structure L1c. In an embodiment, as compared to the semiconductor device 1, a first structure ST1 may further include first bonding pads BP1, and a second structure ST2 may further include second bonding pads BP2 bonded to the first bonding pads BP1. The first bonding pads BP1 and the second bonding pads BP2 may form a bonding surface J. For example, a first bonding layer 53 may be coplanar with the first bonding pads BP1, and a second bonding layer 110 may be coplanar with the second bonding pads BP2. Each of the first bonding pads BP1 may be electrically connected to the cell interconnection structure L1c or the peripheral interconnection structure L1p.

In an embodiment, the second structure ST2 may further include a connection structure 115 electrically connecting cell through-vias 120cand peripheral through-vias 120p to the second bonding pads BP2. The connection structure 115 may include interconnection layers extending in the horizontal direction, and vias connecting the interconnection layers to the cell through-vias 120c and the peripheral through-vias 120p or to the second bonding pads BP2. In an embodiment, a horizontal width of each of the cell through-vias 120c and a horizontal width of each of the peripheral through-vias 120p may be changed toward the first structure ST1. For example, a horizontal width of each of the cell through-vias 120c and a horizontal width of each of the peripheral through-vias 120p may increase toward the first structure ST1.

The semiconductor device 1b may be formed by separately forming the first structure ST1 and the second structure ST2 each including the first bonding pads BP1 and the second bonding pads BP2, and then bonding the first structure ST1 and the second structure ST2.

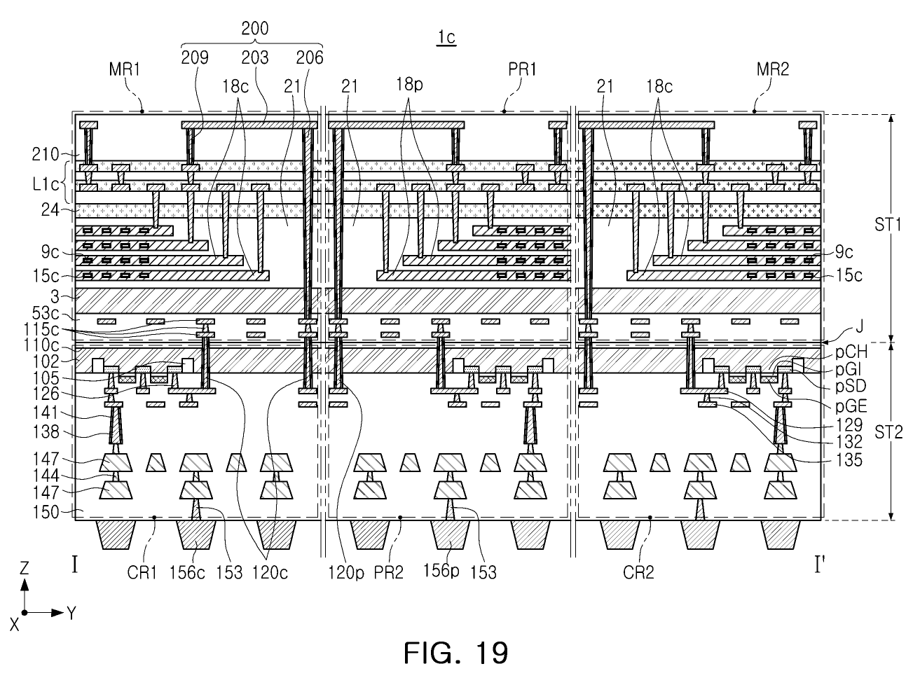

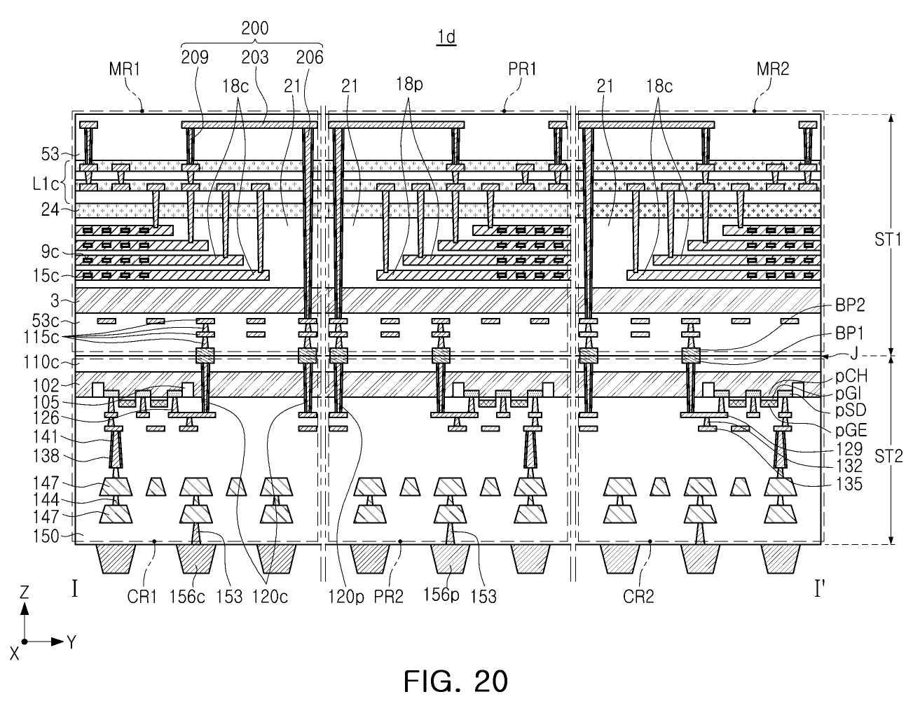

FIGS. 19 and 20 are vertical cross-sectional views of semiconductor devices according to example embodiments.

Referring to FIG. 19, a semiconductor device 1c may include a first structure ST1 and a second structure ST2 vertically overlapping the first structure ST1. For example, the semiconductor device 1c may have a cell-on-peri (COP) structure, and the first structure ST1 may be disposed on the second structure ST2.

In an embodiment, the first structure ST1 may include a first bonding layer 53c disposed below a first substrate 3, and the second structure ST2 may include a second bonding layer 110c disposed on a second substrate 102. The first bonding layer 53c may be bonded to the second bonding layer 110c. The first structure ST1may include a connection structure 115c in the first bonding layer 53c. The connection structure 115c may include interconnection layers extending in the horizontal direction and vias connecting the interconnection layers.

The first structure ST1 may include an upper insulating layer 210 and a routing interconnection structure 200 in the upper insulating layer 210, on a cell interconnection structure L1c and a peripheral interconnection structure L1p. The routing interconnection structure 200 may include an interconnection layer 203 on the cell interconnection structure L1c and the peripheral interconnection structure L1p, a routing via 209 connecting the interconnection layer 203 to the cell interconnection structure L1c and the peripheral interconnection structure L1p, and a routing via 206 connecting the interconnection layer 203 to the connection structure 115c. The routing via 209 may be disposed on the cell interconnection structure L1c and the peripheral interconnection structure L1p, and may extend in the vertical direction. The routing via 209 may penetrate the first substrate 3, an interlayer insulating layer 21, the cell interconnection structure L1c and the peripheral interconnection structure L1p, and may extend in the vertical direction.

In an embodiment, a horizontal width of the routing via 206 and a horizontal width of the routing via 209 may be changed toward the second structure ST2. For example, a horizontal width of the routing via 206 and a horizontal width of the routing via 209 may decrease toward the second structure ST2.

The second structure ST2 may include a cell through-via 120c and a peripheral through-via 120p. The cell through-via 120c and the peripheral through-via 120p may pass through the second substrate 102, and may be electrically connected to the connection structure 115c. For example, the cell through-via 120c and the peripheral through-via 120p may pass through the second bonding layer 110c, and may be in contact with the connection structure 115c.

In an embodiment, a horizontal width of the cell through-via 120c and a horizontal width of the peripheral through-via 120p may be changed toward the first structure ST1. For example, a horizontal width of the cell through-via 120c and a horizontal width of the peripheral through-via 120p may decrease toward the first structure ST1.

The semiconductor device 1c may be formed by bonding a preliminary structure SUB including the second substrate 102 to the first structure ST1 using the second bonding layer 110c, and then performing processes of S140 to S170 of FIG. 9.

Referring to FIG. 20, a semiconductor device 1d may include a first structure ST1 disposed on a second structure ST2. In an embodiment, as compared to the semiconductor device 1c, the first structure ST1 may further include first bonding pads BP1, and the second structure ST2 may further include second bonding pads BP2 bonded to the first bonding pads BP1. The first bonding pads BP1 and the second bonding pads BP2 may form a bonding surface J. For example, a first bonding layer 53c may be coplanar with the first bonding pads BP1, and a second bonding layer 110c may be coplanar with the second bonding pads BP2. Each of the first bonding pads BP1 may be electrically connected to a connection structure 115c.

In an embodiment, a horizontal width of each of cell through-vias 120c and a horizontal width of each of peripheral through-vias 120p may be changed toward the first structure ST1. For example, a horizontal width of each of cell through-vias 120c and a horizontal width of each of peripheral through-vias 120p may increase toward the first structure ST1.

The semiconductor device 1d may be formed by separately forming the first structure ST1 and the second structure ST2 each including the first bonding pads BP1 and the second bonding pads BP2, and then bonding the first structure ST1 and the second structure ST2.

A method for manufacturing a semiconductor device according to example embodiments may include forming a first structure including a first substrate, wherein the first substrate includes a memory cell region and a first peripheral circuit region; bonding a preliminary structure including a peripheral transistor on the first structure; forming a cell through-via and a peripheral through-via penetrating a second substrate of the preliminary structure in a vertical direction; forming a lower interconnection structure and an upper interconnection structure connected to the cell through-via and the peripheral through-via on the second substrate; and forming an input/output pad on the lower interconnection structure and the upper interconnection structure.

The forming a first structure may include forming a cell transistor on the first substrate; forming an information storage structure connected to the cell transistor on the first substrate; and forming a cell interconnection structure and a peripheral interconnection structure on the cell transistor and the information storage structure.

The cell interconnection structure may be formed on the memory cell region, and the peripheral interconnection structure may be formed on the first peripheral circuit region.

The peripheral interconnection structure may be formed simultaneously with the cell interconnection structure, and may be disposed at the same level as the cell interconnection structure.

The cell interconnection structure may be electrically connected to the cell through-via, and the peripheral interconnection structure may be electrically connected to the peripheral through-via.

The cell transistor may include cell active patterns extending in a first horizontal direction and stacked to be spaced apart from each other in the vertical direction; cell gate electrodes surrounding the cell active patterns and extending in a second horizontal direction, intersecting the first horizontal direction; and cell gate dielectric layers between the cell active patterns and the cell gate electrodes.

The peripheral through-via may be formed simultaneously with the cell through-via, and may be disposed at the same level as the cell through-via.

The first structure may further include a first bonding layer on the first substrate, and the second structure may further include a second bonding layer disposed below the second substrate and bonded to the first bonding layer.

The cell through-via and the peripheral through-via may penetrate a bonding surface between the first bonding layer and the second bonding layer.

The lower interconnection structure may electrically connect the peripheral transistor to the cell through-via and the peripheral through-via.

According to embodiments of the technical idea of the present inventive concept, since a peripheral interconnection structure may be disposed at the same level as a cell interconnection structure, the number of interconnection layers of a semiconductor device may be reduced, and a size of the semiconductor device may be reduced. In addition, since a horizontal width of each of peripheral interconnection layers of the peripheral interconnection structure may be formed to be relatively large, resistance of the peripheral interconnection structure may be reduced.

Various advantages and effects of the present inventive concept may not be limited to the contents, and may be more easily understood in the process of explaining specific embodiments.

While example embodiments have been shown and described above, it will be apparent to those skilled in the art that modifications and variations could be made without departing from the scope of the present inventive concept as defined by the appended claims.

What is claimed is:

1. A semiconductor device comprising:
a first structure including a first substrate, wherein the first substrate includes a memory cell region and a first peripheral circuit region;
a second structure overlapping the first structure in a vertical direction and including a second substrate, wherein the second substrate includes a core circuit region and a second peripheral circuit region; and
peripheral through-vias penetrating the second substrate in the vertical direction and electrically connected to the first structure,
wherein the memory cell region includes:
cell active patterns extending in a first horizontal direction and disposed to be spaced apart from each other in the vertical direction;
a cell bit line extending in the vertical direction and contacting the cell active patterns;
cell gate electrodes overlapping the cell active patterns in the vertical direction and extending in a second horizontal direction, intersecting the first horizontal direction; and
a cell interconnection structure disposed on the cell active patterns, the cell bit line, and the cell gate electrodes, and electrically connected to at least one of the cell bit line or the cell gate electrodes,
wherein the first peripheral circuit region includes:
peripheral active patterns extending in the first horizontal direction;
a peripheral bit line extending in the vertical direction and contacting the peripheral active patterns;
peripheral gate electrodes overlapping the peripheral active patterns in the vertical direction and extending in the second horizontal direction; and
a peripheral interconnection structure disposed on the peripheral active patterns, the peripheral bit line and the peripheral gate electrodes, and electrically connected to at least one of the peripheral bit line or the peripheral gate electrodes,
wherein the peripheral through-vias are electrically connected to the peripheral interconnection structure.

2. The semiconductor device of claim 1, wherein the cell interconnection structure includes cell interconnection layers electrically connected to the cell gate electrodes,
the peripheral interconnection structure includes peripheral interconnection layers electrically connected to the peripheral gate electrodes, and
a horizontal width of one of the peripheral interconnection layers is greater than a horizontal width of one of the cell interconnection layers.

3. The semiconductor device of claim 2, wherein the peripheral interconnection layers are disposed at the same level as the cell interconnection layers.

4. The semiconductor device of claim 2, wherein the cell interconnection structure includes a cell via connecting the cell interconnection layers,
the peripheral interconnection structure includes a peripheral via connecting the peripheral interconnection layers, and
a horizontal width of the peripheral via is greater than a horizontal width of the cell via.

5. The semiconductor device of claim 1, wherein the peripheral through-vias penetrate a bonding surface between the first structure and the second structure.

6. The semiconductor device of claim 1, wherein at least one of the peripheral gate electrodes is disposed at the same level as at least one of the cell gate electrodes.

7. The semiconductor device of claim 1, wherein at least one of the peripheral active patterns is disposed at the same level as at least one of the cell active patterns.

8. The semiconductor device of claim 1, wherein the first peripheral circuit region is disposed on one side of the memory cell region in the second horizontal direction, and overlaps the second peripheral circuit region in the vertical direction.

9. The semiconductor device of claim 1, wherein the core circuit region overlaps the memory cell region in the vertical direction.

10. A semiconductor device comprising:
a first structure including a first substrate, wherein the first substrate includes a memory cell region and a first peripheral circuit region;
a second structure overlapping the first structure in a vertical direction and including a second substrate, wherein the second substrate includes a core circuit region and a second peripheral circuit region; and
peripheral through-vias penetrating the second substrate in the vertical direction and electrically connected to the first structure,
wherein the memory cell region includes:
cell active patterns extending in a first horizontal direction and disposed to be spaced apart from each other in the vertical direction;
a cell bit line extending in the vertical direction and contacting the cell active patterns;
cell gate electrodes overlapping the cell active patterns in the vertical direction and extending in a second horizontal direction, intersecting the first horizontal direction; and
a cell interconnection structure disposed on the cell active patterns, the cell bit line, and the cell gate electrodes, and electrically connected to at least one of the cell bit line or the cell gate electrodes,
wherein the first peripheral circuit region includes a peripheral interconnection structure disposed at the same level as the cell interconnection structure,
wherein the cell interconnection structure includes cell interconnection layers disposed to be spaced apart from each other in the vertical direction, and cell vias connecting the cell interconnection layers,
wherein the peripheral interconnection structure includes peripheral interconnection layers and a peripheral via, disposed at the same level as the cell interconnection layers and the cell via, respectively,
wherein a horizontal width of one of the peripheral interconnection layers is greater than a horizontal width of one of the cell interconnection layers, and
wherein the peripheral through-vias are electrically connected to the peripheral interconnection structure.

11. The semiconductor device of claim 10, wherein the first structure is disposed on the second structure,
the first structure further includes a first bonding layer on the cell interconnection structure and the peripheral interconnection structure, and
the second structure further includes a second bonding layer disposed below the second substrate and bonded to the first bonding layer.

12. The semiconductor device of claim 11, wherein the peripheral through-vias penetrate a bonding surface between the first structure and the second structure.

13. The semiconductor device of claim 12, wherein a horizontal width of one of the peripheral through-vias decreases toward the first structure.

14. The semiconductor device of claim 11, wherein the first structure further includes first bonding pads coplanar with the first bonding layer, and
the second structure further includes second bonding pads coplanar with the second bonding layer and bonded to the first bonding pads.

15. The semiconductor device of claim 14, wherein a horizontal width of one of the peripheral through-vias increases toward the first structure.

16. The semiconductor device of claim 14, wherein the second structure further includes a connection structure disposed between the peripheral through-vias and the second bonding pads and electrically connecting the peripheral through-vias to the second bonding pads.

17. The semiconductor device of claim 10, wherein the second structure is disposed on the first structure,
the first structure further includes a first bonding layer disposed below the first substrate, and
the second structure further includes a second bonding layer disposed on the second substrate and bonded to the first bonding layer.

18. The semiconductor device of claim 17, wherein the peripheral through-vias penetrate a bonding surface between the first structure and the second structure.

19. The semiconductor device of claim 17, wherein the first structure further includes first bonding pads coplanar with the first bonding layer, and
the second structure further includes second bonding pads coplanar with the second bonding layer and bonded to the first bonding pads.

20. A semiconductor device comprising:
a first structure including a first substrate, wherein the first substrate includes a memory cell region and a first peripheral circuit region;
a second structure overlapping the first structure in a vertical direction and including a second substrate, wherein the second substrate includes a core circuit region and a second peripheral circuit region; and
peripheral through-vias penetrating the second substrate in the vertical direction and electrically connected to the first structure,
wherein the memory cell region includes:
cell active patterns extending in a first horizontal direction and disposed to be spaced apart from each other in the vertical direction;
a cell bit line extending in the vertical direction and contacting the cell active patterns;
cell gate electrodes overlapping the cell active patterns in the vertical direction and extending in a second horizontal direction, intersecting the first horizontal direction; and
a cell interconnection structure disposed on the cell active patterns, the cell bit line, and the cell gate electrodes, and electrically connected to at least one of the cell bit line or the cell gate electrodes,
wherein the first peripheral circuit region includes:
peripheral active patterns extending in the first horizontal direction;
a peripheral bit line extending in the vertical direction and contacting the peripheral active patterns;
peripheral gate electrodes overlapping the peripheral active patterns in the vertical direction and extending in the second horizontal direction; and
a peripheral interconnection structure disposed on the peripheral active patterns, the peripheral bit line and the peripheral gate electrodes, and electrically connected to at least one of the peripheral bit line or the peripheral gate electrodes,
wherein the second peripheral circuit region includes:
a peripheral transistor on the second substrate;
a lower interconnection structure disposed on the peripheral transistor and connected to the peripheral transistor and the peripheral through-via;
an upper interconnection structure on the lower interconnection structure; and
an input/output pad on the upper interconnection structure,
wherein the peripheral through-vias are electrically connected to the peripheral interconnection structure.
